(19) United States
(12) Patent Application Publication
(10) Pub. No.: US 2013/0143011 A1
(43) Pub. Date: Jun. 6, 2013

(54) PHOTOSENSITIVE RESIN COMPOSITION

(71) Applicant: Hitachi Chemical DuPont MicroSystems, Ltd., Tokyo (JP)

(72) Inventors: Keiko Suzuki, Ibaraki (JP); Noriyuki Yamazaki, Ibaraki (JP); Mamoru Sasaki, Ibaraki (JP); Tomonori Minegishi, Ibaraki (JP)

(73) Assignee: HITACHI CHEMICAL DUPONT MICROSYSTEMS, LTD., Tokyo (JP)

(21) Appl. No.: 13/670,817

(22) Filed: Nov. 7, 2012

(30) Foreign Application Priority Data
Dec. 2, 2011 (JP) 2011-264788

(51) Int. Cl. G03F 7/004

(52) U.S. Cl. CPC G03F 7/0045
USPC 428/201; 430/283.1; 430/325; 428/195.1

(57) ABSTRACT

A photosensitive resin composition including: (a) a polyamide acid; (b) a compound (b1) having 4 or more of a methylol group, a methoxymethyl group and the both thereof, or a compound (b2) represented by the following formula (2); and (c) a photopolymerization initiator.

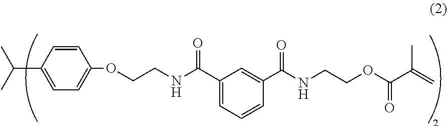

### TECHNICAL FIELD

The invention relates to a photosensitive resin composition, a method for producing a cured film using the photosensitive resin composition and a circuit formation substrate having a cured film comprising the photosensitive resin composition.

### BACKGROUND ART

In recent years, in respect of an increase in memory capacity or an increase in processing speed or the like of a hard disc drive, as the magnetic head (hereinafter referred to as the “head”), a MR (magnet-resistive) thin film composite head in which a magnet-resistive device and a thin film are integrated has attracted attention. Since the number of terminals of the MR-thin film composite head is twice as large as those of conventional heads, it is required to decrease the diameter of a wire connecting the head and the disc main body. As the method for decreasing the diameter of a wire, a method in which a circuit is directly formed on a circuit formation substrate which is a substrate for suspension on which a head is mounted can be mentioned.

As the protective layer or the insulating layer of the circuit formation substrate, a polyimide resin which has excellent heat resistance, electric properties and mechanical properties has been used (Patent Document 1).

### RELATED ART DOCUMENTS

### Patent Document

### Patent Document 1: JP-A-2008-122889

### SUMMARY OF THE INVENTION

In the meantime, as for the cured film of a resin which is used in the protective layer or the insulating layer of the circuit formation substrate, in respect of appearance, it is preferred that it can hide the circuit formed on the substrate. For that purpose, the transparency of the cured film in the visible ray range is required to be low. In order to decrease the transparency of the cured film, studies have been made to incorporate a known colorant such as Green-DCF (2-N,N-diphenylamino-6-diethylaminofluoran) or the like into a photosensitive resin composition, which is a precursor of the cured film. However, incorporation of a colorant has a problem that the light transmittance in the ultraviolet ray region (365 to 420 nm, for example) of the photosensitive resin composition is lowered, and as a result, a pattern cannot be formed even though UV exposure is conducted.

In order to solve the above-mentioned subject, the invention is aimed at providing a photosensitive resin composition which is capable of obtaining a photosensitive resin film which can form a good pattern excellent in resolution, and is also capable of obtaining a cured film which has low transparency in the visible ray region. The invention is also aimed at providing a method for producing a cured film using a photosensitive resin composition and a circuit formation substrate having a cured film which is obtained from the photosensitive resin film.

According to the invention, the photosensitive resin composition comprising the following components (a) to (c) is provided:
(a) a polyamide acid having a structural unit represented by the following formula (1);
(b) a compound (b1) having 4 or more of a methylol group, a methoxymethyl group or the both thereof, or a compound (b2) represented by the following formula (2); and
(c) a photopolymerization initiator;

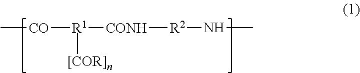

wherein in the formula (1), R¹ is a trivalent or tetravalent organic group and R² is a divalent organic group; and R is a monovalent organic group having a carbon-carbon unsaturated double bond or a group represented by —O⁻M⁺ in which a compound having a carbon-carbon unsaturated double bond is ionically bonded wherein M⁺ is a hydrogen ion or an anion formed of a compound having a carbon-carbon unsaturated double bond and hydrogen; and n is 1 or 2.

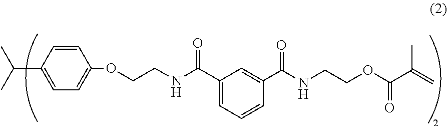

Further, in the invention, it is preferred that the above-mentioned compound (b1) having 4 or more of a methylol group, a methoxymethyl group or the both thereof be a photosensitive resin composition represented by the following formula (3), (4) or (5):

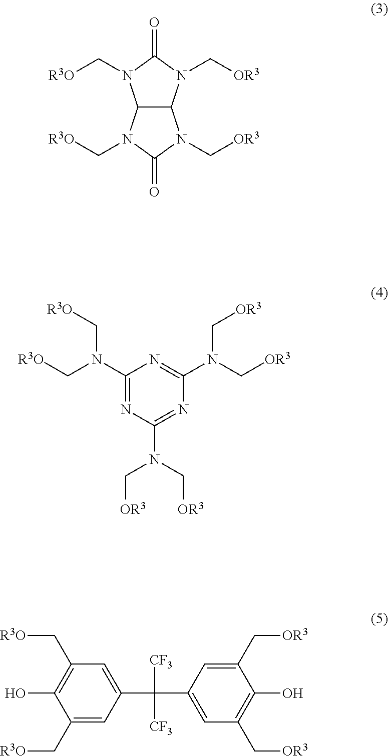

wherein in the formulas (3), (4) and (5), R³s are independently a hydrogen atom or a methyl group.

It is preferred that the photosensitive resin composition of the invention be a photosensitive resin composition wherein the component (b) is contained in an amount of 2 to 10 parts by mass relative to 100 parts by mass of the component (a).

The photosensitive resin composition of the invention is preferable as a photosensitive resin composition for forming a protective layer or an insulating layer of a circuit formation substrate of a suspension of a hard disc drive.

In another aspect of the invention, there is provided a method for producing a cured film comprising the steps of:

applying the photosensitive resin composition to a substrate, followed by drying to form a photosensitive resin film;

exposing the photosensitive resin film to light, followed by developing, to obtain a patterned resin film; and

heating the patterned resin film.

In another aspect of the invention, there is provided a circuit formation substrate having the cured film obtained by the method as an insulating layer or a protective layer.

In another aspect of the invention, there is provided a circuit formation substrate having a substrate, an insulating layer, a conductive layer and a protective layer in this sequence.

In another aspect of the invention, there is provided a suspension of a hard disc drive having the circuit formation substrate.

According to the invention, it is possible to provide a photosensitive resin film capable of forming a good pattern which is excellent in resolution, as well as a cured film which has a low transparency after curing. In addition, since a cured film obtained by curing the photosensitive resin composition of the invention has a low thermal expansion coefficient and a low hygroscopic expansion coefficient, it is possible to suppress the curving of the circuit formation substrate.

Further, by the method for producing a cured film using the photosensitive resin composition of the invention, it is possible to form a good pattern excellent in resolution of the photosensitive resin film. Further, the circuit formation substrate having the cured film obtained by the production method of the invention as a protective layer or an insulating layer, due to a well-shaped pattern and excellent mechanical properties, a suspension of a hard disc drive having high reliability can be provided.

### BRIEF DESCRIPTION OF THE DRAWINGS

FIG. 1 is a schematic cross-sectional view explaining the steps of forming a circuit formation substrate using the photosensitive resin composition according to the embodiment of the invention;

FIG. 2 is a schematic cross-sectional view explaining the steps of forming a circuit formation substrate using the photosensitive resin composition according to the embodiment of the invention;

FIG. 3 is a schematic cross-sectional view explaining the steps of forming a circuit formation substrate using the photosensitive resin composition according to the embodiment of the invention;

FIG. 4 is a schematic cross-sectional view explaining the steps of forming a circuit formation substrate using the photosensitive resin composition according to the embodiment of the invention;

FIG. 5 is a schematic cross-sectional view explaining the steps of forming a circuit formation substrate using the photosensitive resin composition according to the embodiment of the invention;

FIG. 6 is a schematic cross-sectional view explaining the steps of forming a circuit formation substrate using the photosensitive resin composition according to the embodiment of the invention;

FIG. 7 is a schematic cross-sectional view explaining the steps of forming a circuit formation substrate using the photosensitive resin composition according to the embodiment of the invention;

FIG. 8 is a schematic cross-sectional view explaining the steps of forming a circuit formation substrate using the photosensitive resin composition according to the embodiment of the invention;

FIG. 9 is a schematic cross-sectional view explaining the steps of forming a circuit formation substrate using the photosensitive resin composition according to the embodiment of the invention; and

FIG. 10 is a schematic plan view showing a suspension of a hard disc drive according to the embodiment of the invention.

### MODE FOR CARRYING OUT THE INVENTION

Hereinbelow, the embodiments of the photosensitive resin composition, a method for producing a cured film using the photosensitive resin composition and the circuit formation substrate of the invention will be explained in detail. The invention is not restricted to these embodiments.

### 1. Photosensitive Resin Composition

The photosensitive resin composition of the invention comprises the following components (a) to (c), or substantially (for example, 90 wt % or more, 95 wt % or more or 98 wt % or more) comprises the following components (a) to (c):
(a) A polyamide acid having a structural unit represented by the formula (1)
(b) A compound (b1) having 4 or more of a methylol group, a methoxymethyl group or the both thereof, or a compound (b2) represented by the formula (2)
(c) A photopolymerization initiator
   [Component (a)]

The polyamide acid used in the invention has a structural unit represented by the following formula (1). The polyamide acid is subjected to dehydration and ring closing during the heating treatment to become a polyimide.

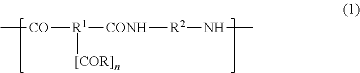

wherein in the formula (1), R¹ is a trivalent or tetravalent organic group and R² is a divalent organic group; R is a monovalent organic group having a carbon-carbon unsaturated double bond or a group represented by —O⁻M⁺ in which a compound having a carbon-carbon unsaturated double bond is ionically bonded wherein M⁺ is a hydrogen ion or an anion formed of a compound having a carbon-carbon unsaturated double bond and hydrogen and n is 1 or 2.

R′ in the formula (1) is generally a residue other than a carboxyl group or an acid anhydride group in tetracarboxylic acid (dianhydride) or tricarboxylic acid (anhydride) used as a raw material. It is preferred that R¹ be a group having an aromatic ring such as a benzene ring. Specific examples thereof include a residue of tetracarboxylic dianhydride or the like, which will be mentioned later.

R² in the formula (1) is generally a residue other than the amino group of diamine used as a raw material. Specific examples thereof include a residue of diamine or the like, which will be mentioned later.

R in the formula (1) is a monovalent organic group having a carbon-carbon unsaturated double bond or a group represented by —O⁻M⁺ in which a compound having a carbon-carbon unsaturated double bond is ionically bonded.

As the monovalent organic group having a carbon-carbon unsaturated double bond, a group containing an acryloyl group, a methacryloyl group, an aryl group or the like can be given. In respect of good reactivity, a group containing an acryloyl group or a methacryloyl group is preferable.

In addition, in a group represented by —O⁻M⁺ in which a compound having a carbon-carbon unsaturated double bond is ionically bonded, M⁺ is a hydrogen ion or an anion formed of a compound having a carbon-carbon unsaturated double unsaturated bond such as an acryloyl group and a methacryloyl group and hydrogen. In the meantime, in “—O⁻M⁺ in which a compound having a carbon-carbon unsaturated double bond is ionically bonded”, a case where M is hydrogen means a case where part of M is “hydrogen” and the remaining part of M is composed of the “compound having a carbon-carbon unsaturated double bond”. In the invention, in at least part of the group, the “compound having a carbon-carbon unsaturated double bond” is always ionically bonded.

As for the group represented by —O⁻M⁺ in which a compound having a carbon-carbon unsaturated double bond is ionically bonded, in respect of imparting a cured film with good mechanical properties, it is preferred that the group be a group in which an acrylate or a methacrylate or the like having an amino group such as dialkylaminoalkyl acrylate or dialkylaminoalkyl methacrylate (for example, the number of carbon atoms of each alkyl is 1 to 10). It is more preferred that the group be represented by the following formula (A).

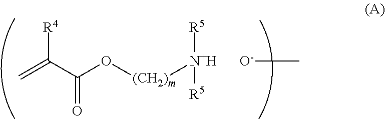

In the formula (A), R⁴ and R⁵, which may be the same or different, are a hydrogen atom or an organic group having 1 to 2 carbon atoms, and m is an integer of 1 to 3.

More specifically, it is particularly preferable that the group be a group represented by CH₂═CH—COO—(CH₂)ₘ—N⁺H(CₙH₂ₙ₊₁)₂.O⁻— or CH₂═C(CH₃)—COO—(CH₂)ₘ—N⁺H(CₙH₂ₙ₊₁)₂.O⁻— wherein m is an integer of 1 to 3 and n is an integer of 1 or 2.

The polyamide acid represented by the formula (1) can be obtained by subjecting tetracarboxylic dianhydride and a diamine compound to addition polymerization, adding an amine having an acryloyl group, a methacryloyl group or the like, followed by stirring, and bonding ionically the resultant to a polyamide acid.

Examples of the tetracarboxylic dianhydride include, though not limited thereto, pyromellitic dianhydride, 3,3′,4,4′-benzophenone tetracarboxylic dianhydride, 3,3′,4,4′-biphenyl tetracarboxylic dianhydride, 4,4′-oxydiphthallic dianhydride, 1,2,5,6-naphthalene tetracarboxylic dianhydride, 1,4,5,8-naphthalene tetracarboxylic dianhydride, 4,4′-sulfonyldiphthalic dianhydride, 2,2-bis(3,4-dicarboxyphenyl)propane dianhydride or the like, for example.

They may be used singly or in combination of two or more.

Examples of the diamine compound include, though not limited thereto, an aromatic diamine such as p-phenylenediamine, m-phenylenediamine, 2,2′-dimethyl-4,4′-diaminobiphenyl, p-xylylenediamine, m-xylylenediamine, 1,5-diaminonaphthalene, benzidine, 3,3′-dimethoxybenzidine, 4,4′-(or 3,4′-, 3,3′-, 2,4′-)diaminophenylmethane, 4,4′-(or 3,4′-, 3,3′-, 2,4′-)diaminodiphenylether, 4,4′-(or 3,4′-, 3,3′-, 2,4′-)diaminodiphenylsulfone, 4,4′-(or 3,4′-, 3,3′-, 2,4′-)diaminodiphenylsulfide, 4,4′-benzophenonediamine, 3,3′-benzophenonediamine, 4,4′-di(4-aminophenoxy)phenylsulfone, 4,4′-bis(4-aminophenoxy)biphenyl, 1,4-bis(4-aminophenoxy)benzene, 1,3-bis(4-aminophenoxy)benzene, 1,1,1,3,3,3-hexafluoro-2,2-bis(4-aminophenyl)propane, 2,2′-bis(trifluoromethyl)benzidine, 2,2-bis[4-(4-aminophenoxy)phenyl]propane, 3,3-dimethyl-4,4′-diaminodiphenylmethane, 3,3′,5,5′-tetramethyl-4,4′-diaminodiphenylmethane, 4,4′-di(3-aminophenoxy)phenylsulfone, 3,3′-diaminodiphenylsulfone, 2,2′-bis(4-aminophenyl)propane, 5,5′-methylene-bis(anthranilic acid), 3,5-diaminobenzoic acid, 3,3′-dihydroxy-4,4′-diaminobiphenyl, 3,3′-dimethyl-4,4′-diaminobiphenyl, 2,2′-dimethyl-4,4′-diaminobiphenyl, 3,3′-dimethyl-4,4′-diaminobiphenyl-6,6′-disulfonic acid; heterocyclic diamine such as 2,6-diaminopyridine, 2,4-d iaminopyridine, 2,4-diamino-s-triazine, 2,7-diaminobenzofuran, 2,7-diaminocarbazole, 3,7-diaminophenothiazine, 2,5-diamino-1,3,4-thiadiazole, 2,4-diamino-6-phenyl-s-triazine, trimethylenediamine, tetramethylenediamine, hexamethylenediamine, 2,2-dimethylpropylenediamine or the like.

They are used singly or in combination of two or more.

As the amine having an acryloyl group, a methacryloyl group or the like, in respect of film properties, it is preferable to use N,N-dialkylaminoalkyl(meth)acrylate (an amine compound having a (meth)acryloyl group) represented by the following formula (6).

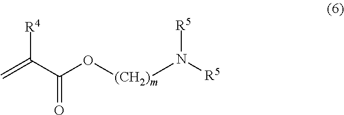

(in the formula (6), R⁴ and R⁵, which may be the same or different, are a hydrogen atom or an organic group having 1 to 2 carbon atoms, and m is an integer of 1 to 3)

In the formula (6), in respect of light curability and heat resistance, it is preferred that R⁴ and R⁵ be respectively a hydrogen atom, a methyl group or an ethyl group.

The polyamide acid which is an intermediate of the formula (1) can be obtained by a method in which a diamine compound is added to a solvent such as NMP to allow it to be dissolved, and tetracarboxylic dianhydride in the same equivalent amount as that of the diamine compound is added to start polymerization.

The weight average molecular weight (Mw) of the polyamide acid intermediate is preferably about 10,000 to 200,000, with 10,000 to 90,000 being more preferable. Here, the weight average molecular weight is measured by the gel permeation chromatography method, and converted by the standard polystyrene. Specifically, it can be measured by a method described in the Examples.

Thereafter, to the solution of the polyamide acid intermediate, an amine having an acryloyl group or a methacryloyl group is added in the same equivalent amount of that of the diamine compound, followed by stirring, whereby a polyamide acid represented by the formula (1) can be obtained.

[Component (b)]

The photosensitive resin composition of the invention comprises, as the component (b), a compound (b1) having 4 or more (for example, 4 to 6) of (b1) methylol group, a methoxymethyl group or the both thereof or a compound (b2) represented by the following formula (2):

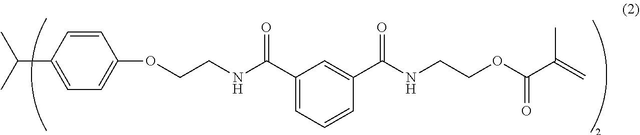

Due to the inclusion of the component (b), the photosensitive resin composition of the invention can form a cured film which has transparency that enables a pattern to be formed at a good resolution at the time of light exposure (for example, transmittance to light having a wavelength of 405 nm of 95% or more of a resin film, after the application and drying of the photosensitive resin composition i.e.) at the time of light exposure and has transparency which is low enough to hide the circuit after curing (for example, transmittance to light having a wavelength of 550 nm of 80% or less after curing). The light transmittance can be measured by means of a spectrophotometer or the like.

As for the component (b), it is preferable to use one which has excellent compatibility with the component (a).

As for the component (b) of the invention, in respect of attaining advantageous effects of the invention sufficiently, that is, exhibiting good transparency at the time of light exposure and exhibiting low transparency after curing, the component (b) is preferably a compound represented by the following formulas (2) to (5). These compounds may be used singly or in combination of two or more.

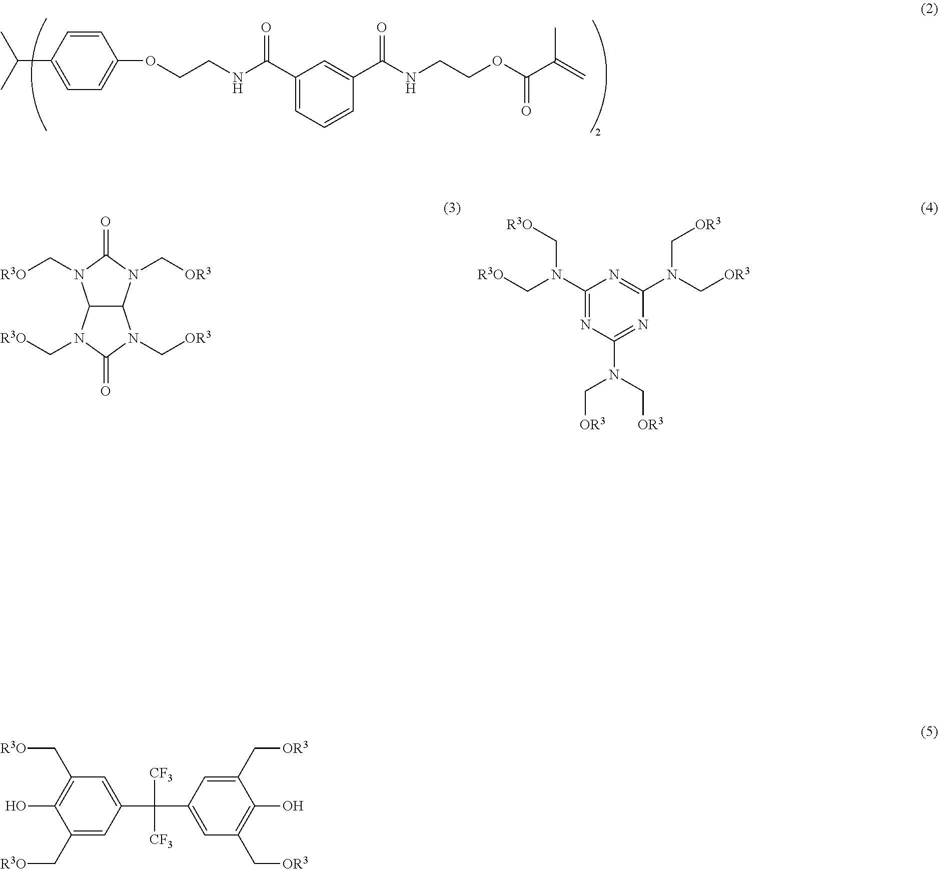

(in the formulas (3), (4) and (5), R³s are independently a hydrogen atom or a methyl group)

Further, in respect of attaining the effects of the invention more effectively, it is preferred that the component (b) be any of the compounds represented by the following formulas.

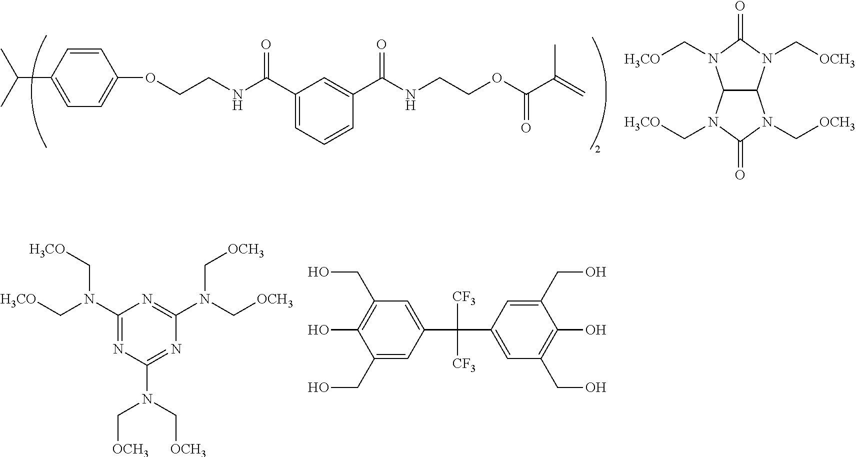

The content of the component (b) used in the invention is preferably 1 to 10 parts by mass relative to 100 parts by mass of the component (a). By using the component (b) in an amount of 1 to 10 parts by mass, transparency of a cured film can be sufficiently lowered. In order to attain the advantageous effects of the invention more effectively, it is more preferred that the component (b) be contained in an amount of 2 to 8 parts by mass, with 3 to 5 parts by mass being further preferable.

[Component (c)]

The component (c) is a photopolymerization initiator which is a compound that generates a radical upon application of active rays. As the component (c), N,N′-tetraalkyl-4,4′-diaminobenzophenone such as benzophenone and N,N′-tetramethyl-4,4′-diaminobenzophenone (Michler ketone), an aromatic ketone such as 2-benzyl-2-dimethylamino-1-(4-morpholinophenyl)-butanone-1 and 2-methyl-1-[4-(methylthio)phenyl]-2-morpholino-propanone-1, a quinone which is fused with an aromatic ring such as alkylanthraquinone, a benzoin ether compound such as benzoin alkyl ether, a benzoin compound such as benzoin and alkyl benzoin, a benzyl derivative such as benzyl dimethyl ketal, a compound represented by the following formula (7), oxime esters and a titanocene-based photopolymerization initiator can be given.

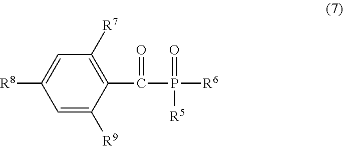

(in the formula (7), R⁵ is an alkyl group having 1 to 20 carbon atoms, an alkyl group having 2 to 20 carbon atoms having one or more oxygen atoms, an alkoxy group having 1 to 12 carbon atoms, an aromatic group or an aromatic group substituted by an alkyl group having 1 to 4 carbon atoms; R⁶ is a group represented by the formula (8) or a group exemplified as R⁵; and R⁷ to R⁹ are independently an alkyl group having 1 to 12 carbon atoms, an alkoxy group having 1 to 12 carbon atoms or a halogen)

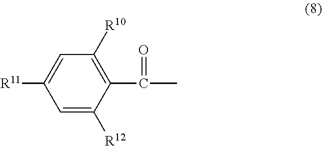

(in the formula (8), R¹⁰to R¹² are groups exemplified as R⁷ to R⁹ in the formula (7)).

Of these, in respect of attaining excellent sensitivity, it is preferable to use an oxime ester or a titanocene-based photopolymerization initiator as the component (c). As examples of an oxime ester, it is preferable to use an oxime ester represented by the following formula (9) in respect of obtaining excellent sensitivity and film remaining ratio.

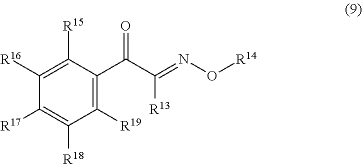

(in the formula (9), R¹³ to R¹⁹ are independently a monovalent organic group)

In the formula (9), R¹³ is preferably an alkyl group having 1 to 10 carbon atoms or more preferably an alkyl group having 4 to 7 carbon atoms. It is more preferred that R¹³ be a hexyl group. R¹⁴ is preferably an organic group having 1 to 10 carbon atoms (an aryl carbonyl group, for example).

As for R¹⁵ to R¹⁹, in respect of excellent sensitivity and film remaining ratio, it is preferred that at least one of R¹⁵ to R¹⁹ be —SR²⁰. It is more preferred that four of R¹⁵ to R¹⁹ be hydrogen and one be —SR²⁰. It is further preferred that R¹⁵, R¹⁶, R¹⁸ and R¹⁹ be hydrogen and R¹⁷ be —SR²⁰. It is preferred that R²⁰ be a cyclohexyl group, a phenyl group or a phenylalkyl group having 7 to 10 carbon atoms. It is more preferred that R²⁰ be a phenyl group or a phenylalkyl group having 7 to 10 carbon atoms, and it is further preferred that R²⁰ be a phenyl group.

In respect of low hygroscopic expansion coefficient, the component (c) is particularly preferably 1,2-octanedione represented by the following formula (10), 1-[4-[phenylthio]-,2-[o-benzoyloxime] or bis(η5-2,4-cyclopentadiene-1-yl)-bis(2,6-difluoro-3-(1H-pyrrole-1-yl)-phenyl)titanium represented by the following formula (11).

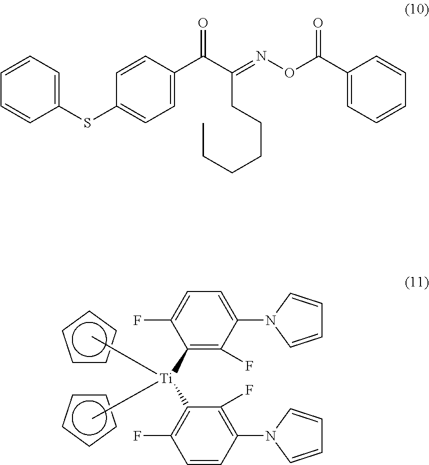

It is preferred that the component (c) be contained in an amount of 1 to 10 parts by mass relative to 100 parts by mass of the component (a). Due to the presence of the component (c) in such an amount, a resin film can have good resolution. Further, it is possible to impart a cured film with excellent mechanical properties. Further, in respect of improving the solubility of a resin film in a developer at the time of development, it is more preferred that the component (c) be contained in an amount of 1 to 8 parts by mass, further preferably 1 to 5 parts by mass.

### [Other Components]

According to need, the photosensitive resin composition of the invention uses a solvent. As the solvent, acetone, methyl ethyl ketone, toluene, chloroform, methanol, ethanol, 1-propanol, 2-propanol, 1-butanol, 2-butanol, t-butanol, ethylene glycol monomethyl ether, propylene glycol monomethyl ether, xylene, tetrahydrofuran, dioxane, N,N-dimethylacetoamide, N,N-dimethylformamide, N-methyl-2-pyrrolidone, γ-butyrolactone, dimethylsufoxide, ethylene carbonate, propylene carbonate, sulfolane, or the like can be given. These solvents are used singly or in combination of two or more.

If the photosensitive resin composition contains a solvent, it is preferred that the solvent be contained in an amount of 100 to 500 parts by mass relative to 100 parts by mass of the component (a).

If necessary, the photosensitive resin composition of the invention may contain a polymerization inhibitor, a dissolution accelerator, a photosensitizer, a light-shielding agent, a stabilizer, an adhesion aid or the like.

A polymerization initiator improves resolution properties of a resin film, and also has effects of enhancing the stability of a photosensitive resin composition during storage. As the polymerization inhibitor, p-methoxyphenol, diphenyl-p-benzoquinone, benzoquinone, hydroquinone, pyrogallol, phenothiazine, resorcinol, orthodinitrobenzene, paradinitrobenzene, metadinitrobenzene, phenanthraquinone, N-phenyl-1-naphthylamine, N-phenyl-2-naphthylamine, cupferron, phenothiazine, 2,5-toluquinone, tannic acid, parabenzylaminophenol, nitrosoamine or the like can be given. They are used singly or in combination of two or more.

When a polymerization inhibitor is contained, the polymerization inhibitor is contained preferably in an amount of 0.01 to 30 parts by mass, more preferably in an amount of 0.05 to 10 parts by mass, relative to 100 parts by mass of the component (a).

As the dissolution accelerator, a sulfonamide derivative is preferable, for example. Examples include benzene sulfonamide, toluene sulfonamide, methoxybenzene sulfonamide, benzene sulfonylanilide, toluene sulfonylanilide, methoxy-toluenesulfonylanilide, acetyl-toluenesulfonylanilide, toluenesulfonyl-N-methylamide, toluenesulfonyl-N-ethylamide, toluenesulfonyl-N-propylamide, toluenesulfonyl-N-butylamide, toluenesulfonyl-N-phenylamide, toluenesulfonyl-N-dimethylamide, toluenesulfonyl-N-diethylamide and toluenesulfonyl-N-diphenylamide. Of these, N-phenylbenzene sulfonamide is preferable due to its particularly excellent effects.

If a dissolution accelerator is contained, it is preferred that it be contained in an amount of 2 to 30 parts by mass, more preferably 3 to 15 parts by mass, relative to 100 parts by mass of the component (a).

The photosensitive resin composition of the invention may contain other components insofar as it does not adversely affect the advantageous effects of the invention.

### 2. Method for Producing a Cured Film

An explanation will be given on the method for producing a cured film of the invention. The method of the invention includes the following steps (A) to (C).
(A) A step in which the photosensitive resin composition of the invention is applied to a substrate and dried to form a photosensitive resin film
(B) A step in which the photosensitive resin film is exposed to light and developed to obtain a patterned resin film
(C) A step in which the patterned resin film is subjected to a heat treatment

### Step (A)

In this step, the above-mentioned photosensitive resin composition of the invention is applied to a substrate by a spray method, a screen printing method, a roll coating method or the like, whereby a photosensitive resin film is formed. As the substrate, a stainless-made substrate or the like can be given.

Subsequently, a drying step is conducted in which the photosensitive resin film is heated at about 70 to 120° C. for about 1 to 8 minutes to remove the solvent in the photosensitive resin film. Due to the drying step, a resin film which is less sticky can be obtained.

The thickness of the photosensitive resin film is normally about 5 μm to 30 μm.

It is preferred that the photosensitive resin film after drying have a transmittance of light having a wavelength of 405 nm of 90% or more, more preferably 93% or more, further preferably 95% or more. If the resin film has a transmittance of 90% or more, the resin film has an improved resolution.

### Step (B)

In this step, the photosensitive resin film formed in the above-mentioned step (A) is irradiated with active rays through a photomask and exposed. As examples of the active rays used for irradiation, ultraviolet rays, far ultraviolet rays, visible rays, electron beam and X-rays can be given. Of these, ultraviolet rays are preferable.

After the irradiation of active rays, non-irradiated parts are removed by a developer, followed by development, whereby a resin film formed into a desired pattern is obtained.

As the developer, a non-flammable solvent such as 1,1,1-trichloroethane, an aqueous alkali solution such as an aqueous sodium carbonate solution and an aqueous tetramethylammonium hydroxide solution, a solvent such as N,N-dimethylformamide, dimethylsulfoxide, N,N-dimethylacetoamide, N-methyl-2-pyrrolidone and γ-butyrolactone, a mixed solvent of these solvents with a lower alcohol, water, an aromatic hydrocarbon or the like. After development, if necessary, rinsing is conducted by using methanol, ethanol, isopropyl alcohol, benzene, toluene, xylene, methyl cellosolve, water or the like.

### Step (C)

In this step, the patterned resin film obtained in the above-mentioned step (B) is heated. As a result, the imide ring of the polyamide acid as the component (a) is opened to obtain a cured film.

The heating temperature is preferably 150 to 500° C., preferably 200 to 400° C. By allowing the heating temperature to be 150 to 500° C., it is possible to impart a cured film with excellent mechanical properties.

It is preferred that the heating time be 5 to 300 minutes.

The transmittance of light with a wavelength of 550 nm of the resulting cured film is preferably 80% or less, more preferably 79% or less, with 78% or less being further preferable. If the transmittance is 80% or less, the cured film can hide a circuit on the circuit formation substrate.

Hereinbelow, an explanation will be made with reference to the drawings on an example in which a protective layer and an insulating layer are formed on the circuit formation substrate by the method for producing a cured film of the invention. The method for forming the protective layer or the insulating layer is not limited by this statement.

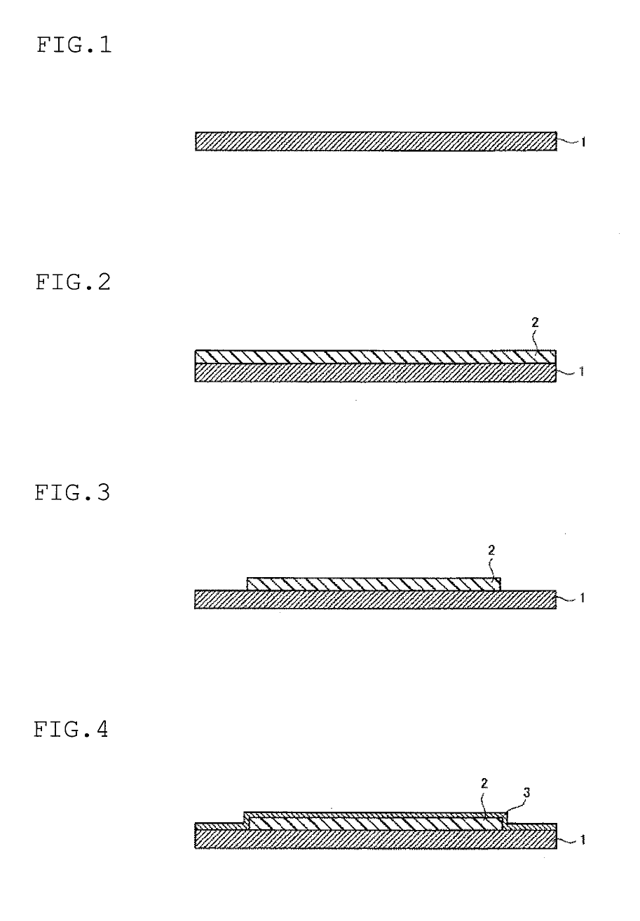

FIGS. 1 to 9 are schematic cross-sectional views for explaining the steps of producing a circuit formation substrate having an insulating layer and a protective layer formed of a cured film of the invention. At first, a substrate 1 formed of stainless foil or the like is prepared (FIG. 1), and to this substrate 1, the photosensitive resin composition of the invention is applied by a spin coater or the like (FIG. 2). After application, by conducting drying, exposure, developing and heating, a patterned insulating layer 2 is formed (FIG. 3).

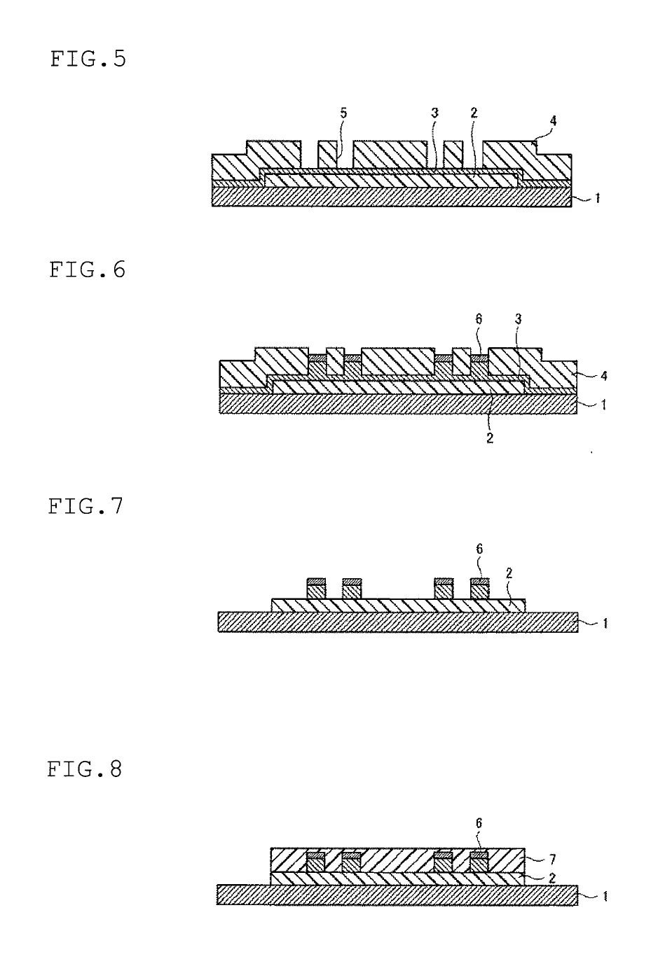

Subsequently, in order to allow a plating film to be grown on the insulating layer 2, a seed layer 3 is formed as a metal layer serving as an undercover (FIG. 4). The seed layer 3 can be formed by subjecting two layers, i.e. a chromium thin film and a copper thin film, to a high-frequency sputtering method or the like. Subsequently, a photoresist 4 is applied to the seed layer 3, followed by light exposure and development, whereby a photoresist pattern is formed (FIG. 5). In an opening part 5 of the photoresist pattern, a circuit conductor formed of a multilayer structure of copper, nickel, gold or the like is stacked by electroplating, whereby a circuit layer 6 is formed (FIG. 6).

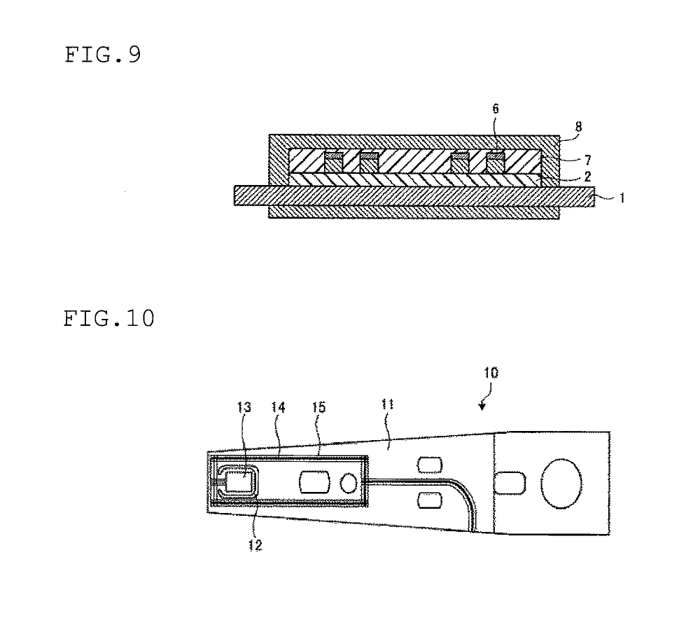

After forming the circuit layer 6, the photoresist 4 is removed by a photoresist remover or the like, and an unnecessary part of the seed layer 3 is removed by etching (FIG. 7). Subsequently, in order to protect the circuit layer 6, the photosensitive resin composition of the invention is applied to the circuit layer 6, followed by drying, exposure, development and heating, whereby a patterned protective layer 7 is formed (FIG. 8). Thereafter, by providing a cover 8 which covers the protective layer 7 and a predetermined part of the substrate 1, the circuit formation substrate having the protective layer and the insulating layer formed of the photosensitive resin composition of the invention can be produced (FIG. 9).

The photosensitive resin composition of the invention can be preferably used for forming the protective layer or the insulating layer of the circuit formation substrate of a suspension of a hard disc drive. In the meantime, it can be used as the protective layer or the insulating layer of the circuit formation substrate such as a flexible printed circuit board or the like.

The circuit formation substrate of a suspension of a hard disc drive of the invention may be a circuit formation substrate in which a substrate, an insulating layer, a conductive layer and a protective layer are provided in this sequence. The substrate is formed of stainless or the like, the conductive layer is formed of copper or the like, and the insulating layer and the protective layer are formed of the photosensitive resin composition of the invention. Between the insulating layer and the conductive layer, a chromium layer or a titanium layer may be formed.

FIG. 10 is a schematic plan view showing one example of a suspension of a hard disc drive having the circuit formation substrate using the photosensitive resin composition of the invention. In FIG. 10, a suspension 10 is a member which is provided with a magnetic head having functions of writing and reading data for a magnetic disc, and serves to control the gap between a magnetic disc and a magnetic head to several tens nm with a high degree of accuracy. The suspension is formed of a plate-like substrate 11 formed of stainless or the like. At the tip of the substrate 11 constituting the suspension 10, a gimbal 13 is integrally formed by a slit 12. On the gimbal 13, a slider (not shown) having a magnetic head is fixed.

In FIG. 10, on the substrate 11, an insulating layer (not shown) formed of the photosensitive resin composition is formed. On the insulating layer, a prescribed pattern circuit formed of a copper conductor layer 14 which is patterned circuit is mounted. Further, on the patterned circuit, a protective layer 15 formed of the photosensitive resin composition of the invention is formed. Since the prescribed pattern circuited is mounted on the substrate 11, this suspension 10 may be called as the “suspension provided with a circuit”.

### EXAMPLES

The invention will be explained in more detail referring to the following examples and comparative examples, which should not be construed as limiting the scope of the invention.

### Synthesis Example 1

### [Synthesis of a polyamide acid (Polymer I)

To 150 ml of N-methyl-2-pyrrolidone, 32.0 g (100 mmol) of 2,2′-bis(trifluoromethyl)benzidine was added and dissolved. Then, 29.4 g (100 mmol) of 3,3′,4,4′-biphenyltetracarboxlic dianhydride was added to start polymerization, whereby a polyamide acid was obtained. The weight-average molecular weight of this polyamide acid obtained by the standard polystyrene conversion was 40,000. Thereafter, to the solution of this polyamide acid, 100 mmol of N,N-dimethylaminopropyl methacrylate was added, followed by stirring, whereby polymer I was obtained.

### Synthesis Example 2

### Synthesis of a polyamide acid (Polymer II)

To 150 ml of N-methyl-2-pyrrolidone, 8.6 g (80 mmol) of p-phenylenediamine and 6.4 g (20 mmol) of 2,2′-bis(trifluoromethyl)benzidine were added and dissolved. Then, 29.4 g (100 mmol) of 3,3′,4,4′-biphenyltetracarboxlic acid dianhydride was added to start polymerization, whereby a polyamide acid was obtained. The weight-average molecular weight of this polyamide acid obtained by the standard polystyrene conversion was 41,400. Thereafter, to the solution of this polyamide acid, 100 mmol of N,N-dimethylaminopropyl methacrylate was added, followed by stirring, whereby polymer II was obtained.

The measurement conditions of the weight-average molecular weight are shown below.
Measurement device: Detector L4000UV manufactured by Hitachi Ltd.
Pump: L6000 manufactured by Hitachi Ltd.

C-R4AChromatopac manufactured by Shimadzu Corporation
Measurement condition: Column Gelpack GL-S300MDT-5×2
Elute: THF/DMF=1/1 (volume ratio)

LiBr (0.03 mol/l), H₃PO₄ (0.06 mol/l)
Flow rate: 1.0 ml/min, detector: UV 270 nm

Measurement was conducted by using a solution comprising 1 ml of a solvent [THF/DMF=1/1 (volume ratio)] relative to 0.5 mg of the polymer.

### Examples 1 to 6 and Comparative Examples 1 and 2

[Preparation of a photosensitive Resin Composition]

In a three-neck flask provided with a stirrer, a thermometer and a nitrogen-introduction tube, the polymer I or II (component (a)) prepared in the Synthesis Examples, the component (b) and the component (c) were blended in an amount ratio shown in Table 1, whereby a photosensitive resin composition was obtained. Unless otherwise specified, the unit of the numerical values shown in Table 1 is the part by mass relative to 100 parts by mass of the polymer.

[Evaluation of Transmittance of a Resin Film before Light Exposure]

The above-mentioned photosensitive resin composition was applied to the silicon wafer by spin coating. The resultant was heated at 70° C. for 2 minutes on a hot plate, followed by further heating at 85° C. for 2 minutes, whereby a 10 μm-thick photosensitive resin film was obtained. The transmittance of light with a wavelength (λ) of 405 nm of the resin film before light exposure was measured. If the light transmittance of the resin film before light exposure is 95% or more, it can be considered that light exposure can be conducted at a good resolution. Meanwhile, the light transmittance was measured by means of a spectrophotometer (U-3410, manufactured by Hitachi, Ltd.).

### [Evaluation of Transmittance of the Cured Film]

The 10 μm-thick photosensitive resin film obtained by the above-mentioned method was irradiated with light by means of a high-pressure mercury lamp. The film was then heated at 200° C. for 30 minutes in an inert gas oven under the atmosphere of nitrogen. The film was further heated at 350° C. for 1 hour to obtain a cured film. For this film, the transmittance of light with a wavelength (λ) of 550 nm was measured. The results are shown in Table 1. It can be considered that if the light transmittance of this film is 80% or less, the film can hide the circuit formed on the circuit formation substrate, and as a result, it is possible to obtain a circuit formation substrate having excellent appearance.

### [Evaluation of Resolution]

The 10 μm-thick photosensitive resin film obtained by the above-mentioned method was exposed to light through a photomask by means of a high-pressure mercury lamp. Thereafter, the film was heated at 105° C. for 1 minute on a hot plate, and then immersed in a developer (N-methyl-2-pyrrolidone) to allow non-irradiated parts to be dissolved. After the non-irradiated parts were completely dissolved, the substrate was taken out from the developer; and then rinsed with isopropyl alcohol. The minimum value of the mask dimension of a square-hole-shaped opening when irradiated by a high-pressure mercury lamp (PLA-600FA) with an exposure amount of 200 mJ/cm² was evaluated as the resolution.

The results are shown in Tablet.

### [Evaluation of Thermal Expansion Coefficient and Hygroscopic Expansion Coefficient]

The above-mentioned photosensitive resin composition was applied to silicon wafer by spin coating. The silicon wafer was heated at 70° C. for 2 minutes on a hot plate, followed by further heating at 85° C. for 2 minutes, whereby a photosensitive resin film was obtained. Thereafter, the resin film was exposed to light by means of a high-pressure mercury lamp. The film was then heat at 200° C. for.30 minutes in an inert gas oven under the atmosphere of nitrogen. The film was furtherheated at 350° C. for 1 hour to obtain a 10 μm-thick cured film.

This cured film was immersed in hydrofluoric acid solution together with the silicon wafer, and the cured film was peeled off from the silicon wafer, washed with water and dried. Then, the thermal expansion coefficient and the hygroscopic expansion coefficient were measured by the following method. The results are shown in Table 1.

### (1) Measurement of Thermal Expansion Coefficient

The cured film which had been peeled off was cut into a piece of 2 mm in width and 20 mm in length for use as an evaluation sample. By means of a thermo-mechanical analysis apparatus (TMA/SS6000, manufactured by Seiko Instruments Inc.), the average coefficient of linear expansion between 100 to 200° C. was measured at a temperature elevation rate of 5° C/min and at a tensile load of 10 g/0.02 mm².

### (2) Hygroscopic Expansion Coefficient

The cured film which had been peeled off was cut into a piece of 5 mm in width and 20 mm in length for use as an evaluation sample. By means of a water vapor atmosphere-thermo-mechanical analysis apparatus (TMA8310, manufactured by Rigaku Corporation), a measurement was conducted. At a temperature of 25° C. and a relative humidity (RH) of 20%, the sample was kept its state for 2 hours for stabilization. Then, the state was kept at a relative humidity (RH) of 80% for 1 hour until the sample became stable. A difference in sample length was divided by a difference in humidity, and the resulting value was taken as a hygroscopic expansion coefficient (tensile load (25 g/0.05 mm²)).

The components (b) and (c) shown in Table 1 are as shown below.

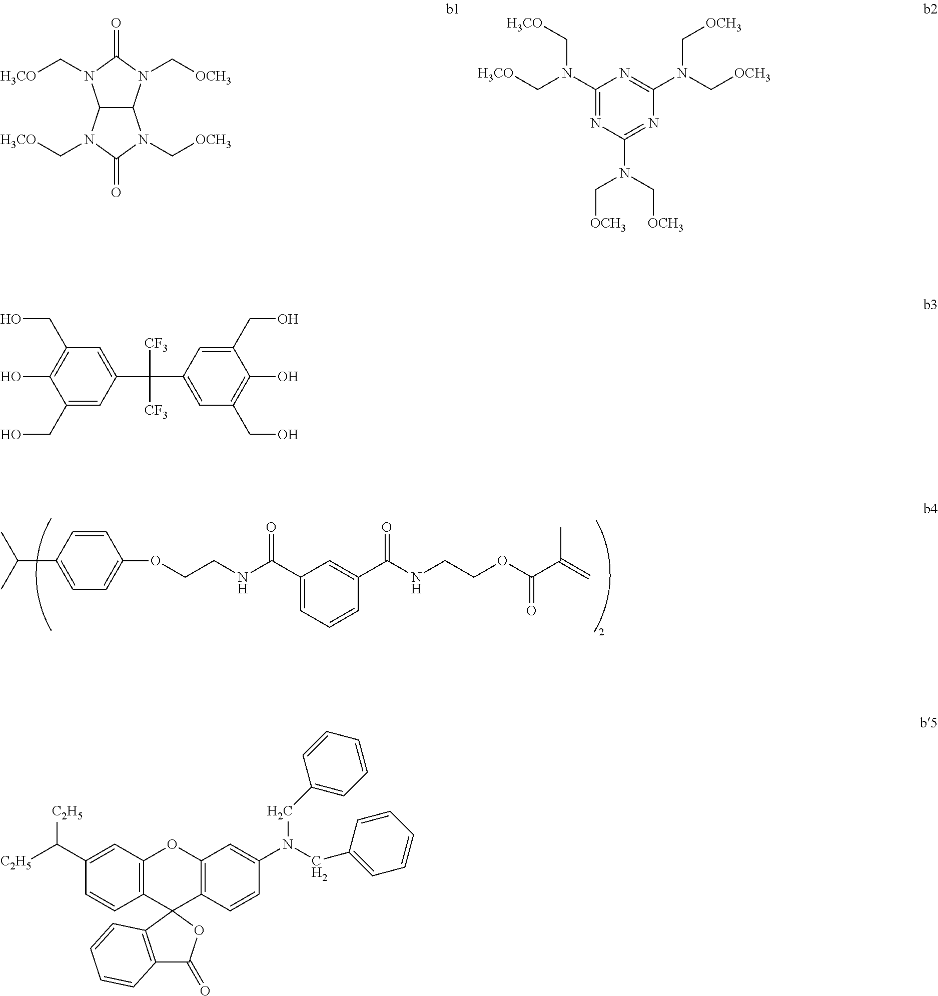

b1: MX-270 manufactured by Sanwa Chemical Co., Ltd.
b2: MX-30HM manufactured by Sanwa Chemical Co., Ltd.
b3: TML-BPAF manufactured by Honshu Chemical Industry
b′5: 2-N,N-dibenzidylamino-6-diethylanninofluorane (Green-DCF, manufactured by Hodogaya Chemical Co., Ltd.)

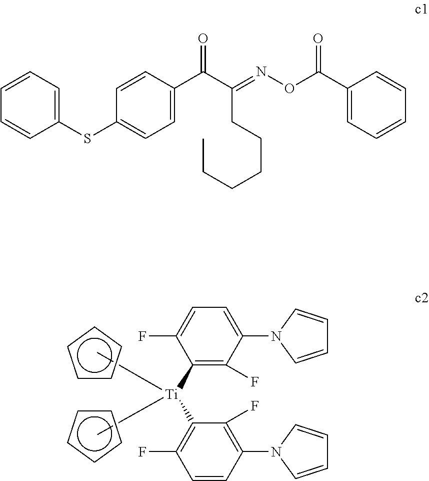

c1: 1,2-octanedione, 1-[4-[phenylothio]-, 2-[o-benzoyloxime)]] (IRGAQUREOXE01 manufactured by Ciba Specialty Chemicals)
c2: bis(η5-2,4-cyclopentadiene-1-yl)-bis(2,6-difluoro-3-(1H-pyrrole-1-yl)-phenyl) titanium) (IRGAQURE784, manufactured by Ciba Specialty Chemicals)

TABLE 1

| | | Examples | | | | | | Com. Ex. | |
|---|---|---|---|---|---|---|---|---|---|
| | | 1 | 2 | 3 | 4 | 5 | 6 | 1 | 2 |
| Component (a) | Polymer I | 100 | 100 | 100 | 100 | 100 | 0 | 100 | 100 |
| | Polymer II | | | | | | 100 | | |
| Component (b) | b1 | 3 | 5 | | | | 3 | | |
| | b2 | | | 3 | | | | | |
| | b3 | | | | 3 | | | | |
| | b4 | | | | | 5 | | | |
| | b′5 | | | | | | | 5 | |
| Component (c) | c1 | 5 | 5 | 5 | 5 | 5 | | 5 | 5 |
| | c2 | | | | | | 5 | | |

| | | | | | | | | |
|---|---|---|---|---|---|---|---|---|
| Light transmittance before | 96 | 96 | 96 | 96 | 99 | 98 | 69 | 99 |
| light exposure | | | | | | | | |
| (λ = 405 nm: %) | | | | | | | | |
| Light transmittance after | 77 | 50 | 15 | 64 | 40 | 78 | 44 | 82 |
| curing (λ = 550 nm: %) | | | | | | | | |
| Resolution (μm) | 7 | 7 | 7 | 7 | 7 | 7 | 50 | 7 |
| Thermal expansion | 17 | 27 | 16 | 20 | 25 | 18 | 26 | 23 |
| coefficient (ppm/° C.) | | | | | | | | |
| Hygroscopic expansion | 11 | 14 | 16 | 13 | 15 | 18 | 16 | 13 |
| coefficient (ppm/%) | | | | | | | | |

As shown in Examples 1 to 6, when a photosensitive resin composition containing the specific component (b) of the invention was used, the resin film before light exposure had a light transmittance (λ=405 nm) of 95% or more, which was high enough to conduct light exposure sufficiently. Further, in each of Examples 1 to 6, the light transmittance (λ=550 nm) after curing was 80% or less, which was low enough to hide the circuit formed on the circuit formation substrate.

In Comparative Example 1 where a known colorant (b′5) was used instead of the component (b), the light transmittance of the resin film before light exposure was low, and hence, the resolution was deteriorated, whereby an excellent pattern could not be formed. In Comparative Example 2 where the component (b) was not used, since the transmittance of the resin film after curing was high, the circuit formed on the circuit formation substrate could not be hidden sufficiently.

### INDUSTRIAL APPLICABILITY

The photosensitive resin composition of the invention can be used preferably as a material for forming a protective layer or an insulting layer of various circuit substrates such as a flexible printed circuit board. The photosensitive resin composition of the invention can be particularly preferably used as a material for forming a protective layer or an insulating layer of a circuit formation substrate of a suspension for a hard disc drive.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of a Japanese application on the basis of which the present application claims Paris convention priority are incorporated herein by reference in its entirety.

1. A photosensitive resin composition comprising:
(a) a polyamide acid having a structural unit represented by the following formula (1);
(b) a compound (b1) having 4 or more of a methylol group, a methoxymethyl group and the both thereof, or a compound (b2) represented by the following formula (2); and
(c) a photopolymerization initiator; 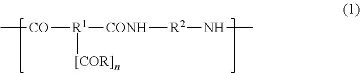
wherein in the formula (1), R¹ is a trivalent or tetravalent organic group and R² is a divalent organic group; and R is a monovalent organic group having a carbon-carbon unsaturated double bond or a group represented by —O⁻M⁺ in which a compound having a carbon-carbon unsaturated double bond is ionically bonded wherein M⁺ is a hydrogen ion or an anion formed of a compound having a carbon-carbon unsaturated double bond and hydrogen; and n is 1 or 2.

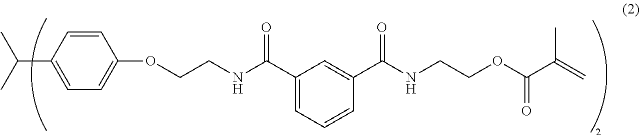

2. The photosensitive resin composition according to claim 1 wherein the compound (b1) having 4 or more of a methylol group, a methoxymethyl group or the both thereof is a compound represented by the following formula (3), (4) or (5): 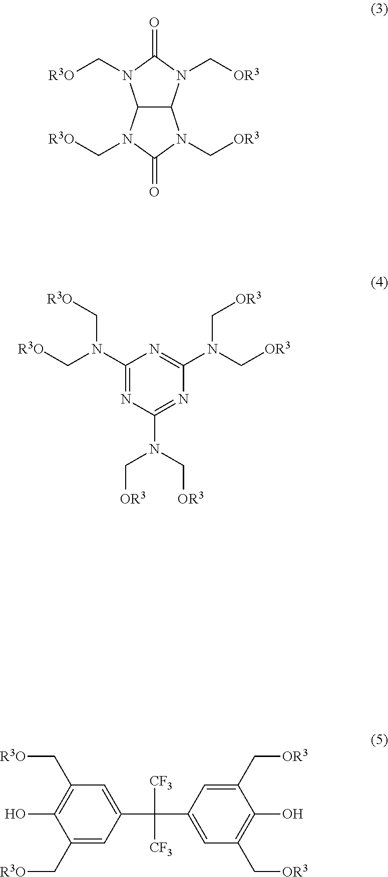
wherein in the formulas (3), (4) and (5), R³s are independently a hydrogen atom or a methyl group.

3. The photosensitive resin composition according to claim 1 wherein the component (b) is contained in an amount of 2 to 10 parts by mass relative to 100 parts by mass of the component (a).

4. The photosensitive resin composition according to claim 1 which is used for forming a protective layer or an insulating layer of a circuit formation substrate of a suspension of a hard disc drive.

5. A cured film obtained by curing the photosensitive resin composition according to claim 1.

6. A method for producing a cured film comprising the steps of:
applying the photosensitive resin composition according to claim 1 to a substrate, followed by drying to obtain a photosensitive resin film;
exposing the photosensitive resin film to light, followed by developing, to obtain a patterned resin film; and
heating the patterned resin film.

7. A circuit formation substrate having the cured film obtained by the method according to claim 6 as an insulating layer or a protective layer.

8. The circuit formation substrate according to claim 7 having a substrate, an insulating layer, a conductive layer and a protective layer in this sequence.

9. A suspension of a hard disc drive having the circuit formation substrate according to claim 7.
